(19) United States
(12) Patent Application Publication
(10) Pub. No.: US 2016/0190510 A1
(43) Pub. Date: Jun. 30, 2016

(54) DISPLAY PANEL, DISPLAY DEVICE AND MANUFACTURING METHOD OF DISPLAY PANEL

(71) Applicants: Xiamen Tianma Micro-Electronics Co., Ltd., Xiamen (CN); Tianma Micro-Electronics Co., Ltd., Shenzhen (CN)

(72) Inventor: Pengbo Li, Xiamen (CN)

(21) Appl. No.: 14/961,858

(22) Filed: Dec. 7, 2015

(30) Foreign Application Priority Data
Dec. 25, 2014 (CN) 201410822705.1

(51) Int. Cl. H01L 51/52; H01L 27/32; H01L 25/16; H01L 51/56

(52) U.S. Cl. CPC H01L 51/5246; H01L 51/56; H01L 27/322; H01L 27/3244; H01L 25/165; H01L 25/167; H01L 2251/566; H01L 2251/5338; H01L 2227/323

(57) ABSTRACT

A display panel, a display device and a manufacturing method of the display panel. The display panel includes a first substrate and a second substrate arranged opposite to the first substrate; the first substrate includes a plurality of first side edges and at least one second side edge, and the second substrate includes a plurality of third side edges and at least one fourth side edge; positions of the first side edges correspond to positions of the third side edges and the first side edges are aligned with the third side edges, and a position of the second side edge corresponds to that of the fourth side edge; at least one notch is arranged on the second side edge, and the length of the notch is smaller than that of the second side edge.

### CROSS-REFERENCE TO RELATED APPLICATION

This application claims priority to Chinese Application No. 201410822705.1, filed Dec. 25, 2014, which is herein incorporated by reference in its entirety.

### TECHNICAL FIELD

The present disclosure relates to the field of display technology and, in particular, to a display panel, a display device, and a manufacturing method of the display panel.

### BACKGROUND

With the development of electronic technology, the manufacturing processes of display panels have become increasingly mature. The existing display panels mainly include liquid crystal display panels, organic light emitting display panels, plasma display panels, and others.

FIG. 1 (A) is a schematic perspective view of a display panel in the related art, and FIG. 1 (B) is a schematic diagram showing the section of the display panel in the related art taken along a line A-A′. As shown in FIG. 1(A) to FIG. 1 (B), the existing display panel includes a first substrate 11, a second substrate 12 arranged opposite to the first substrate 11, an integrated circuit 13, a connection terminal 14 and a flexible printed circuit board 15. The integrated circuit 13 and the connection terminal 14 are both arranged on a surface of the second substrate 12 that faces to the first substrate 11, and the integrated circuit 13 and the flexible printed circuit board 15 are both electrically connected with the connection terminal 14, where the length of a first lateral surface 16 of the first substrate 11 that extends towards the integrated circuit 13 is smaller than the length of a second lateral surface 17 of the second substrate 12 that extends towards the integrated circuit 13, so that an outer lead bonding (OLB) step of the second substrate 12 is formed with respect to the first substrate 11, with the length of the OLB step being equal to the length difference between the first lateral surface 16 and the second lateral surface 17. The integrated circuit 13 and the connection terminal 14 are arranged at the OLB step of the second substrate 12.

The defect in the related art lies in that the strength of the display panel at the OLB step is weak, thus, when the display panel falls or is impacted and hence one side of the OLB step is directly subjected to an external force, the stress at the OLB step of the second substrate 12 is concentrated, thus the OLB step is more likely to break.

### SUMMARY

The disclosure provides a display panel, a display device and a manufacturing method of the display panel.

The disclosure provides a display panel, including a first substrate and a second substrate arranged opposite to the first substrate; the first substrate includes a plurality of first side edges and at least one second side edge, and the second substrate includes a plurality of third side edges and at least one fourth side edge; the positions of the first side edges correspond to positions of the third side edges and the first side edges are aligned with the third side edges, and the position of the second side edge corresponds to that of the fourth side edge; at least one notch is arranged on the second side edge, and the length of the notch is smaller than that of the second side edge.

The disclosure further provides a display device, including the above-mentioned display panel.

The disclosure further provides a manufacturing method of a display panel. The manufacturing method includes: providing a first substrate; providing a second substrate; where the first substrate includes a plurality of first side edges and at least one second side edge, and the second substrate includes a plurality of third side edges and at least one fourth side edge; adhering the first substrate with the second substrate, where positions of the first side edges correspond to positions of the third side edges and the first side edges are aligned with the third side edges, and a position of the second side edge corresponds to that of the fourth side edge; cutting a first pattern off from the second side edge of the first substrate; removing glass of the first pattern from the first substrate.

According to the display panel, the display device and the manufacturing method of the display panel provided by the disclosure, the positions of the first side edges of the first substrate correspond to the positions of the third side edges of the second substrate and the first side edges are aligned with the third side edges, and the position of the second side edge of the first substrate corresponds to that of the fourth side edge of the second substrate, such that the first substrate is aligned with the second substrate, and at least one notch is arranged on the second side edge. In the display panel provided by the disclosure, for solving the problem that the OLB step is vulnerable to fragmentation, the notch is arranged on the first substrate, moreover, the first substrate is aligned with the second substrate, thereby reducing the fragmentation probability of the display panel in the case of fall or impact, avoiding the stress concentration problem of the display panel and enhancing the strength of the display panel.

While multiple embodiments are disclosed, still other embodiments of the disclosure will become apparent to those skilled in the art from the following detailed description, which shows and describes illustrative embodiments of the disclosure. Accordingly, the drawings and detailed description are to be regarded as illustrative in nature and not restrictive.

### BRIEF DESCRIPTION OF THE DRAWINGS

To illustrate technical solutions in embodiments of the disclosure or in the related art more clearly, a brief introduction on the accompanying drawings used for the description of the embodiments or the related art will be given below. The accompanying drawings for the description below illustrate merely some of the embodiments of the disclosure. Some other drawings may be derived from the accompanying drawings.

FIG. 1 (A) is a schematic perspective view of a display panel in the related art;

FIG. 1 (B) is a schematic sectional diagram of a display panel in the related art;

FIG. 2 (A) is a schematic sectional diagram of a display panel, according to embodiments of the disclosure;

FIG. 2 (B) is a schematic perspective view of the display panel, according to embodiments of the disclosure;

FIG. 2 (C) is a schematic plan view of the display panel, according to embodiments of the disclosure;

FIG. 3 (A) is a schematic sectional diagram of a display panel, according to embodiments of the disclosure;

FIG. 3 (B) is a schematic perspective view of the display panel, according to embodiments of the disclosure;

FIG. 3 (C) is a schematic plan view of the display panel, according to embodiments of the disclosure;

FIG. 4 (A) is a schematic perspective view of a display panel, according to embodiments of the disclosure;

FIG. 4 (B) is a schematic plan view of the display panel, according to embodiments of the disclosure;

FIG. 4 (C) is a schematic plan view of the display device, according to embodiments of the disclosure;

FIG. 5 (A) is a flowchart of a manufacturing method of a display panel, according to embodiments of the disclosure;

FIG. 5 (B) is a schematic diagram of substrates, according to embodiments of the disclosure;

FIG. 5 (C) is a schematic diagram of adhering the substrates, according to embodiments of the disclosure;

FIG. 5 (D) is a schematic diagram of cutting the substrates, according to embodiments of the disclosure; and

FIG. 5 (E) is a schematic diagram of fragmenting the substrates, according to embodiments of the disclosure.

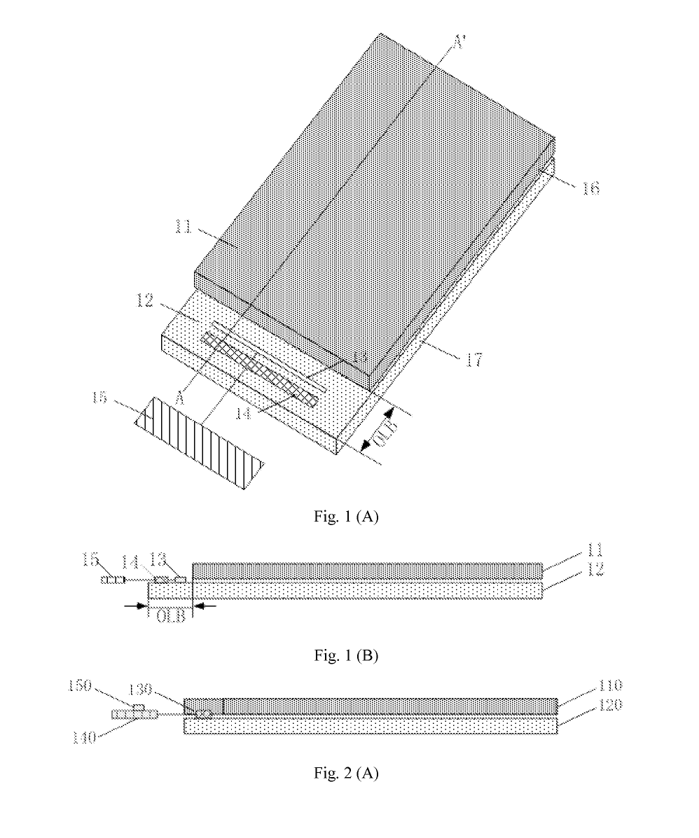

While the disclosure is amenable to various modifications and alternative forms, specific embodiments have been shown by way of example in the drawings and are described in detail below. The intention, however, is not to limit the disclosure to the particular embodiments described. On the contrary, the disclosure is intended to cover all modifications, equivalents, and alternatives falling within the scope of the disclosure as defined by the appended claims.

### DETAILED DESCRIPTION

In order to make purposes, technical solutions and advantages of the disclosure apparent, the technical solutions of the disclosure will be clearly and completely described in combination with embodiments of the disclosure below with reference to the accompanying drawings for the embodiments. The embodiments described are merely a part, but not all, of the embodiments of the disclosure. Other embodiments based on the described embodiments of the disclosure fall into the protection scope of the disclosure.

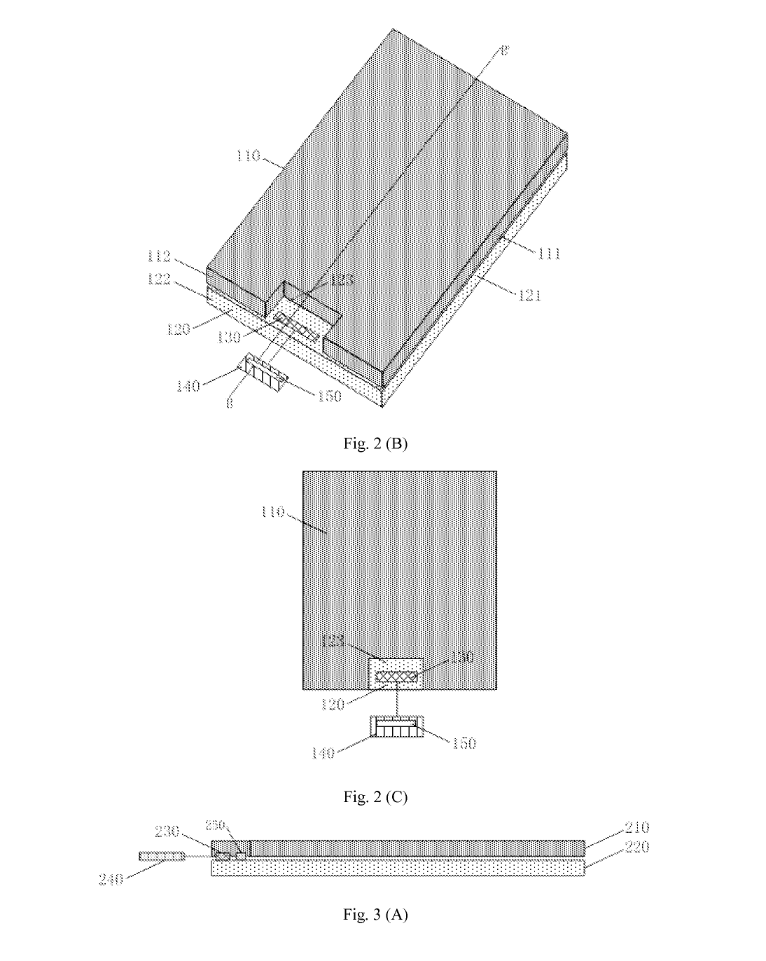

FIG. 2 (A) shows a schematic sectional view of a display panel, according to embodiments of the disclosure. In embodiments, the concentrated stress in the existing display panel, which likely leads to fragmentation vulnerability of the display panel, can be avoided. To illustrate the structure of the display panel shown in FIG. 2 (A) more clearly, further detailed illustration of FIG. 2 (A) is given in combination with the schematic diagrams of the display panel shown in FIG. 2 (B) and FIG. 2 (C), where FIG. 2 (B) is a schematic perspective view of the display panel, according to embodiments of the disclosure, and FIG. 2 (C) is a schematic plan view of the display panel, according to embodiments of the disclosure. The section of the display panel shown in FIG. 2 (B) taken along B-B′ is shown in FIG. 2 (A), and the top plan view of the display panel shown in FIG. 2 (B) taken along a direction facing to the first substrate is shown in FIG. 2 (C).

The display panel includes a first substrate 110, a second substrate 120 arranged opposite to the first substrate 110, a connection terminal 130, a flexible printed circuit board 140, and an integrated circuit 150 arranged on the flexible printed circuit board 140.

The first substrate 110 includes a plurality of first side edges 111 and at least one second side edge 112, and the second substrate 120 includes a plurality of third side edges 121 and at least one fourth side edge 122. The positions of the first side edges 111 correspond to those of the third side edges 121 and the first side edges 111 are aligned with the second side edges 121, while the position of the second side edge 112 corresponds to that of the fourth side edge 122. At least one notch 123 is arranged on the second side edge 112, and the length of the notch 123 is smaller than that of the second side edge 112.

In embodiments, the first substrate 110 includes the first side edges 111 and the second side edge 112, the difference between the first side edges 111 and the second side edge 112 lies in that: no notch 123 is disposed on the first side edges 111 of the first substrate 110, but at least one notch 123 is disposed on the second side edge 112 of the first substrate 110, and the length of the notch 123 is smaller than that of the second side edge 112. The second substrate 120 is arranged opposite to the first substrate 110, and the second substrate 120 includes the third side edges 121 and the fourth side edge 122.

As such, in the display panel, the specific structures of the first substrate 110 and the second substrate 120 are as follows: the positions of the third side edges 121 of the second substrate 120 respectively correspond to those of the first side edges 111 of the first substrate 110 and the first side edges 111 are aligned with the third side edges 121, and the position of the fourth side edge 122 corresponds to that of the second side edge 112 and the fourth side edge 122 is aligned with the second side edge 112. It can thus be seen that, the position of any side edge of the first substrate 110 corresponds to that of a side edge of the second substrate 120 and the side edge of the first substrate 110 and the side edge of the second substrate 120 are aligned with each other, and the second side edge 112 of the first substrate 110 is provided with at least one notch 123, thus a portion of the fourth side edge 122 of the second substrate 120, which is at the position corresponding to the notch 123 on the second side edge 112, is not covered by the first substrate 110.

In embodiments, the display panel can be a liquid crystal display panel, and in an example, the first substrate 110 is a color filter substrate, the second substrate 120 is an array substrate, and at least one notch 123 is arranged on one or more side edges of the color filter substrate. Optionally, the display panel can be an organic light emitting display panel, and in an example, the first substrate 110 is an organic light emitting cover plate, the second substrate 120 is an organic light emitting array substrate, and at least one notch 123 is arranged on one or more side edges of the organic light emitting cover plate.

To conveniently form the notch 123 on the first substrate 110, the notch 123 is designed to have a regular shape such as a parallelogram shape, a trapezoid shape, a rectangular shape or the like. The regular shape of the notch 123 is advantageous in that the process of cutting the second side edge 112 of the first substrate 110 to form the regular notch 123 is relatively simple and there is no need for a change to processes in the existing manufacturing flow, thus the manufacturing flow is very mature without adding additional processes, thereby saving or reducing the manufacturing cost of the display panel. As shown in FIG. 2 (A) to FIG. 2 (C), the notch 123 in the display panel has a rectangle shape.

After the first substrate 110 and the second substrate 120 are formed, with the first substrate 110 having the rectangular notch 123 for example, the connection terminal 130 is arranged at a position on the fourth side edge 122 of the second substrate 120, which corresponds to the notch 123 on the second side edge 112. The connection terminal 130 is electrically connected with the flexible printed circuit board 140.

Given that the connection terminal 130 is arranged at the position on the fourth side edge 122 of the second substrate 120 that corresponds to the notch 123, the flexible printed circuit board 140 may be electrically connected with the connection terminal 130, and the integrated circuit 150 is arranged on the flexible printed circuit board 140 and is electrically connected with the connection terminal 130 through the flexible printed circuit board 140. In embodiments, by taking advantage of numerous wirings in the flexible printed circuit board 140, the integrated circuit 150 is disposed on the flexible printed circuit board 140 and is electrically connected with the connection terminal 130, resulting in a simple manufacturing process, further too much space of the second substrate 120 is not occupied, so that the display panel may be lighter and thinner.

The structure of the display panel has an advantage of enhancing the strength of the display panel. An OLB step is arranged on the second substrate 12 in the related art and is most vulnerable to fragmentation in the display panel, however in the present embodiment, the notch 123 is arranged in the first substrate 110 of the display panel, to accordingly reduce the fragmentation vulnerability phenomenon at the side of the OLB step of the display panel; further, the positions of the corresponding side edges of the first substrate 110 and the second substrate 120 correspond to each other, so that the first substrate 110 is aligned with the second substrate 120, thus compared with the related art, the structural strength of the OLB step is improved; furthermore, with the structure of the display panel in these embodiments, when the display panel falls or the side edge thereof is impacted, the first substrate 110 and the second substrate 120 are simultaneously subjected to almost the same reduced impact or stress, rather than that merely the first substrate 110 or the second substrate 120 is subjected to a high impact or stress, thus the stress is dispersed to reduce the fragmentation probability of a certain one of the first and second substrates due to concentrated stress and avoid the problem of the stress concentration in the display panel. Thus it can be seen that, due to the structure of the display panel in the embodiments of FIGS. 2 (A) to 2 (C), the strength of the display panel is enhanced, and the fragmentation probability of the OLB step is reduced.

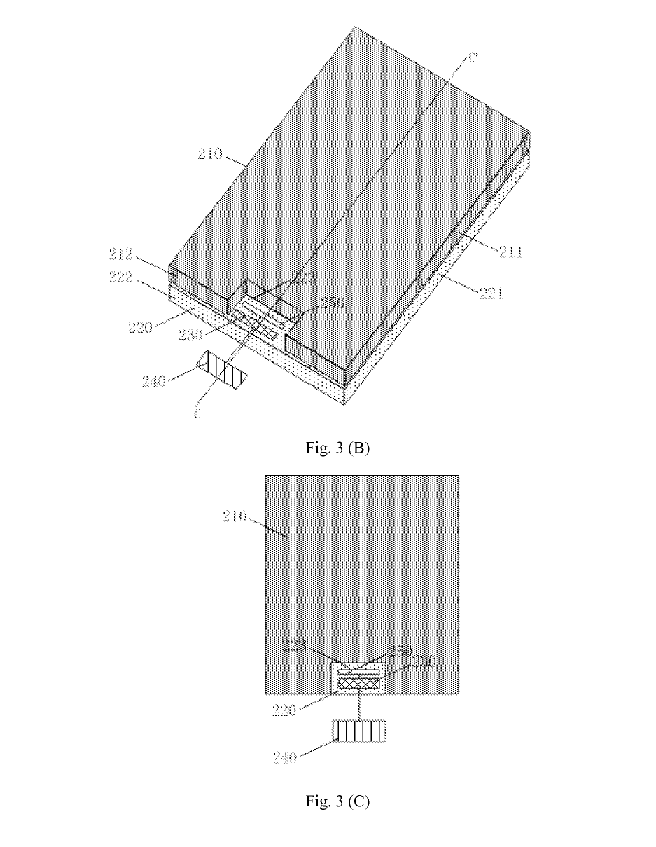

FIG. 3 (A) is a schematic diagram showing a section of a display panel, according to embodiments of the disclosure. FIG. 3 (B) is a schematic perspective view of the display panel, according to embodiments of the disclosure. FIG. 3 (C) is a schematic plan view of the display panel, according to embodiments of the disclosure. The section of the display panel in FIG. 3 (B) taken along a section line C-C′ is shown in FIG. 3 (A), and the top plan view of the display panel in FIG. 3 (B) along the direction facing to the first substrate is shown in FIG. 3 (C).

The display panel includes a first substrate 210, a second substrate 220, a connection terminal 230, a flexible printed circuit board 240 and an integrated circuit 250.

The first substrate 210 includes a plurality of first side edges 211 and at least one second side edge 212, and the second substrate 220 includes a plurality of third side edges 221 and at least one fourth side edge 222; the positions of the first side edges 211 of the first substrate 210 correspond to those of the third side edges 221 of the second substrate 220 and the first side edges 211 are aligned with the third side edges 221, and the position of the second side edge 212 of the first substrate 210 corresponds to that of the fourth side edge 222 of the second substrate 220, to align the first substrate 210 with the second substrate 220. Further, at least one notch 223 is arranged on the second side edge 212. A connection terminal 230 and an integrated circuit 250 are arranged at a position on the fourth side edge 222 of the second substrate 220 which corresponds to the notch 223, and the integrated circuit 250 and the flexible printed circuit board 240 are both electrically connected with the connection terminal 230.

In the display panel, the notch 223 is arranged in the first substrate 210 to solve the fragmentation vulnerability problem of the OLB step in the related art and reduce the fragmentation probability of the OLB step, and moreover, the first substrate 210 is aligned with the second substrate 220, to avoid the stress concentration problem of the second substrate in the related art and enhance the strength of the display panel.

The display panel described above is changed only in the structure, but has advantages of avoiding the defect of stress concentration, reducing the fragmentation probability of the display panel and enhancing the strength of the display panel, but properties such as display performance and transmittance of the display panel are not changed with the structural change.

The properties of a liquid crystal display panel are described below with reference to the schematic perspective view of the display panel shown in FIG. 3 (B). The first substrate 210 is embodied as a color filter substrate, the second substrate 220 is embodied as an array substrate, a liquid crystal layer (not shown) is arranged between the color filter substrate and the array substrate, at least one notch 223 is arranged on the second side edge 212 of the color filter substrate, the connection terminal 230 and the integrated circuit 250 are arranged at a position on the fourth side edge 222 of the array substrate that corresponds to the notch 223, and the connection terminal 230 is electrically connected with the flexible printed circuit board 240. The integrated circuit 250 and the flexible printed circuit board 240 are configured to respectively transmit electric signals to the array substrate through the connection terminal 230. Under the action of an external electric signal, liquid crystal molecules in the liquid crystal layer are sequentially arranged. When hitting the sequentially arranged liquid crystal molecules, the emitted light is regularly deflected, and passes through and exits from the color filter substrate, thus the liquid crystal display panel emits light. Therefore, the structure of the display panel in this embodiment does not cause any change to the properties such as display performance and the transmittance of the liquid crystal display panel.

The properties of an organic light emitting display panel are described below with reference to the schematic perspective view of the display panel shown in FIG. 3 (B). The first substrate 210 is embodied as an organic light emitting cover plate, the second substrate 220 is embodied as an organic light emitting array substrate, an organic light emitting layer (not shown) is arranged on the organic light emitting array substrate, the connection terminal 230 and the integrated circuit 250 are arranged at a position on the fourth side edge 222 of the organic light emitting array substrate that corresponds to the notch 223, and the connection terminal 230 is electrically connected with the flexible printed circuit board 240. The integrated circuit 250 is configured to directly transmit electric signals to the organic light emitting array substrate through the connection terminal 230, so that the electric signals from the integrated circuit 250 may be received by the organic light emitting array substrate through the connection terminal 230. Under the action of external electric signals, the organic light emitting layer is electrically driven to emit light, and the emitted light is transmitted between the organic light emitting cover plate and the organic light emitting array substrate and exits from the organic light emitting cover plate, so that the organic light emitting display panel emits light. Thus, the structure of the display panel in this embodiment does not cause any change to the properties such as display performance and the transmittance of the organic light emitting display panel.

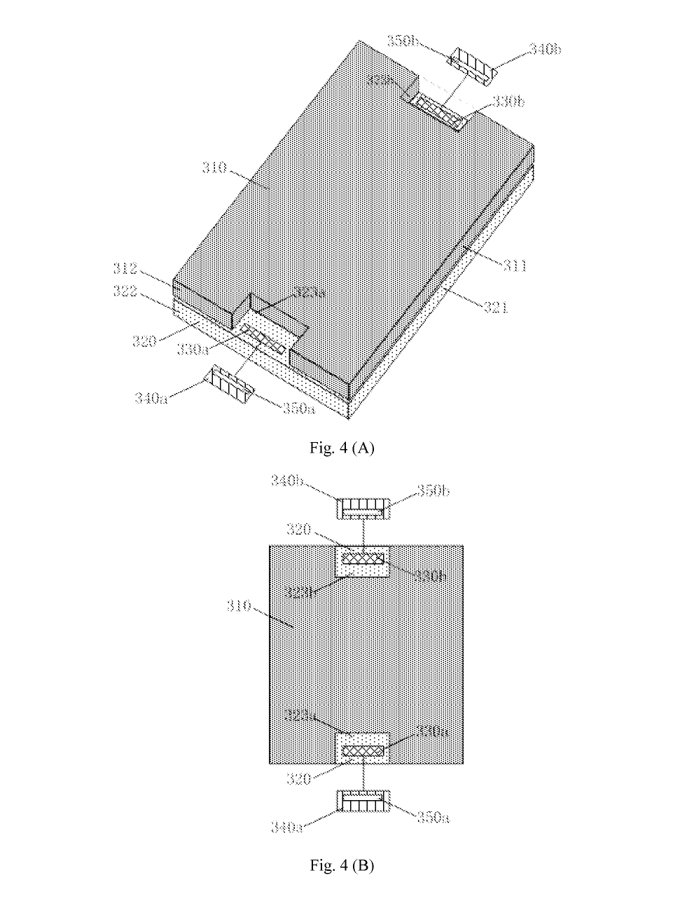

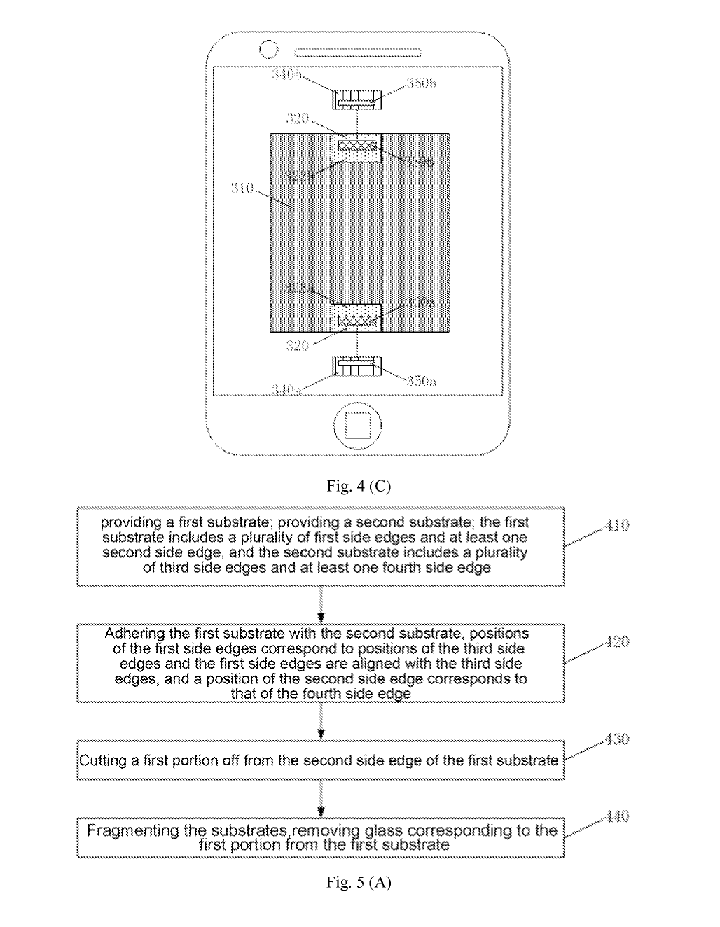

FIG. 4 (A) is a schematic perspective view of a display panel, according to embodiments of the disclosure, and the top plan view of the display panel shown in FIG. 4 (A) along the direction facing to the first substrate is shown in FIG. 4 (B).

The display panel includes a first substrate 310, a second substrate 320 arranged opposite to the first substrate 310, a connection terminal 330a, a flexible printed circuit board 340a electrically connected with the connection terminal 330a, an integrated circuit 350a located on the flexible printed circuit board 340a, a connection terminal 330b, a flexible printed circuit board 340b electrically connected with the connection terminal 330b, and an integrated circuit 350b located on the flexible printed circuit board 340b.

The first substrate 310 includes a plurality of first side edges 311 and a plurality of second side edges 312, the second substrate 320 includes a plurality of third side edges 321 and a plurality of fourth side edges 322, a notch 323a and a notch 323b are arranged on at least two second side edges 312, the connection terminal 330a is arranged at a position on the second substrate 320 that corresponds to the notch 323a, and the connection terminal 330b is arranged at a position on the second substrate 320 that corresponds to the notch 323b.

As shown in FIG. 4 (B), the notch 323a and the notch 323b are arranged on at least two second side edges 312 of the display panel. Here, the notch 323a and the notch 323b disposed on the two second side edges 312 of the display panel have a rectangle shape, for example.

In addition to the notches arranged on the two second side edges 312 of the display panel, the notches 323 can also be arranged on more or all of the second side edges 312 of the display panel, and the notches 323 can have a regular shape such as a trapezoid shape, a parallelogram shape and a rectangular shape.

FIG. 4 (C) is a schematic plan view of a display device, according to embodiments of the disclosure, and the display device includes the display panel shown in FIG. 4 (B), and is applicable to a display device such as a mobile phone, a computer, and a TV set.

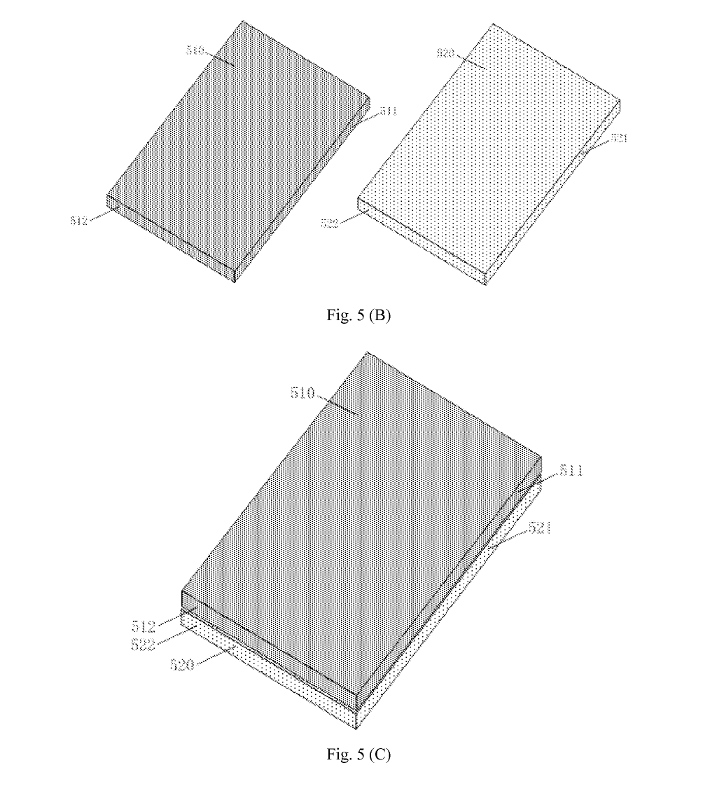

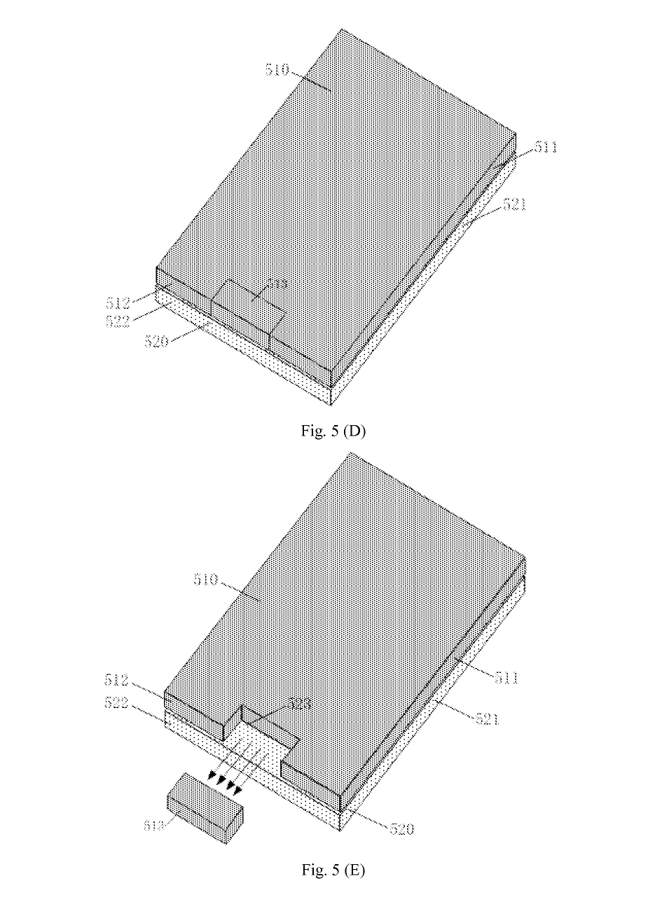

Embodiments of the disclosure provide a manufacturing method of a display panel. FIG. 5 (A) is a flowchart of the manufacturing method of a display panel, according to embodiments of the disclosure, and the manufacturing method, as described in detail in combination with FIG. 5 (B) to FIG. 5 (E), includes Steps 410, 420, 430 and 440.

At Step 410, as shown in FIG. 5 (B), a first substrate 510 is provided. If a liquid crystal display panel is manufactured, the first substrate 510 is a color filter substrate, and if an organic light emitting display panel is manufactured, the first substrate 510 is an organic light emitting cover plate.

At Step 410, a second substrate 520 is further provided. If the provided first substrate 510 is the color filter substrate, the second substrate 520 arranged opposite to the first substrate 510 is an array substrate, and if the provided first substrate 510 is the organic light emitting cover plate, the second substrate 520 is embodied as an organic light emitting array substrate.

The first substrate 510 includes a plurality of first side edges 511 and at least one second side edge 512, and the second substrate 520 includes a plurality of third side edges 521 and at least one fourth side edge 522.

At Step 420, as shown in FIG. 5 (C), the first substrate 510 is adhered to the second substrate 520, where the positions of the first side edges 511 correspond to those of the third side edges 521 and the first side edges 511 are aligned with the third side edges 521, and the position of the second side edge 512 corresponds to that of the fourth side edge 522.

At Step 430, as shown in FIG. 5 (D), a first portion 513 is cut off from the second side edge 512 of the first substrate 510 by a cutting tool, where the length of the first portion 513 is smaller than that of the second side edge 512. The first portion 513 may have a trapezoidal shape, a rectangular shape, a parallelogram shape and so on, and the first portion 513 having a rectangular shape is taken as an example shown in FIG. 5 (D).

At Step 440, as shown in FIG. 5 (E), the substrates are fragmented, glass corresponding to the first portion 513 is separated from the first substrate 510 and removed from the second side edge 512 of the first substrate 510, to form at least one notch 523 on the second side edge 512 of the first substrate 510.

In this way, the structures of the first substrate 510 and the second substrate 520 of the display panel are manufactured. A connection terminal is arranged at a position on the second substrate 520 that corresponds to the notch 523, a flexible printed circuit board is electrically connected with the connection terminal, and an integrated circuit of the display panel is arranged in the flexible printed circuit board. Or, in the structures of the first substrate 510 and the second substrate 520 of the display panel as manufactured in this way, the connection terminal and the integrated circuit are arranged at a position on the second substrate 520 that corresponds to the notch 523, and the integrated circuit and the flexible printed circuit board are both electrically connected with the connection terminal.

According to the manufacturing method of the display panel, according to embodiments of the disclosure, the first substrate 510 and the second substrate 520 are adhered to each other and aligned with each other, the first portion 513 is cut off from the second side edge 512 of the first substrate 510 to form a notch, so that a circuit of the display panel is disposed at a position on the fourth side edge 522 of the second substrate 520 that corresponds to the notch. The structure of the display panel manufactured by the method is changed, but the display performance of the display panel is not affected, and the display panel has the advantages of enhanced strength and reduced fragmentation probability, and the stress concentration problem is avoided. The manufacturing method of the present disclosure does not need any change of the existing manufacturing flow which is very mature, and no additional technical process is added, thereby saving the manufacturing cost and time of the display panel.

Although embodiments and adopted technical principles of the disclosure have been described as above, those skilled in the art will appreciate that the disclosure is not limited to the specific embodiments described herein, and various variations, readjustments and substitutions can be made without departing from the protection scope of the disclosure. Thus, although the disclosure has been described in detail in combination with the above embodiments, the disclosure is not limited to the above embodiments, and other embodiments can be made without departing from the concept of the disclosure, and the scope of the disclosure is defined by the appended claims.

Various modifications and additions can be made to the exemplary embodiments discussed without departing from the scope of the disclosure. For example, while the embodiments described above refer to particular features, the scope of this disclosure also includes embodiments having different combinations of features and embodiments that do not include all of the described features. Accordingly, the scope of the disclosure is intended to embrace all such alternatives, modifications, and variations as fall within the scope of the claims, together with all equivalents thereof.

I claim:

1. A display panel, comprising a first substrate and a second substrate arranged opposite to the first substrate;
wherein the first substrate comprises a plurality of first side edges and at least one second side edge, and the second substrate comprises a plurality of third side edges and at least one fourth side edge;
positions of the first side edges correspond to positions of the third side edges and the first side edges are aligned with the third side edges, and a position of the second side edge corresponds to that of the fourth side edge; and
at least one notch is arranged on the second side edge, and a length of the notch is smaller than that of the second side edge.

2. The display panel of claim 1, wherein the first substrate is a color filter substrate, and the second substrate is an array substrate.

3. The display panel of claim 1, wherein the first substrate is an organic light emitting cover plate, and the second substrate is an organic light emitting array substrate.

4. The display panel of claim 1, wherein the notch has a trapezoid, rectangular or parallelogram shape.

5. The display panel of claim 1, wherein a connection terminal is arranged at a position on the fourth side edge of the second substrate that corresponds to the notch.

6. The display panel of claim 5, further comprising a flexible printed circuit board, which is electrically connected with the connection terminal.

7. The display panel of claim 1, further comprising an integrated circuit, which is arranged at a position on the fourth side edge of the second substrate that corresponds to the notch.

8. A display device, comprising a display panel comprising a first substrate and a second substrate arranged opposite to the first substrate;
wherein the first substrate comprises a plurality of first side edges and at least one second side edge, and the second substrate comprises a plurality of third side edges and at least one fourth side edge;
positions of the first side edges correspond to positions of the third side edges and the first side edges are aligned with the third side edges, and a position of the second side edge corresponds to that of the fourth side edge; and
at least one notch is arranged on the second side edge, and a length of the notch is smaller than that of the second side edge.

9. The display device of claim 8, wherein the first substrate is a color filter substrate, and the second substrate is an array substrate.

10. The display device of claim 8, wherein the first substrate is an organic light emitting cover plate, and the second substrate is an organic light emitting array substrate.

11. The display device of claim 8, wherein the notch has a trapezoid, rectangular or parallelogram shape.

12. The display device of claim 8, wherein a connection terminal is arranged at a position on the fourth side edge of the second substrate that corresponds to the notch.

13. The display device of claim 12, further comprising a flexible printed circuit board, which is electrically connected with the connection terminal.

14. The display device of claim 8, further comprising an integrated circuit, which is arranged at a position on the fourth side edge of the second substrate that corresponds to the notch.

15. A manufacturing method of a display panel, comprising:
providing a first substrate;
providing a second substrate; wherein the first substrate comprises a plurality of first side edges and at least one second side edge, and the second substrate comprises a plurality of third side edges and at least one fourth side edge;
adhering the first substrate with the second substrate, wherein positions of the first side edges correspond to positions of the third side edges and the first side edges are aligned with the third side edges, and a position of the second side edge corresponds to that of the fourth side edge;
cutting a first portion off from the second side edge of the first substrate; and
removing glass corresponding to the first portion from the first substrate.

16. The manufacturing method of claim 15, wherein the first portion is cut off to form at least one trapezoidal, rectangular or parallelogram shaped notch.
